(19) United States
(12) Patent Application Publication
(10) Pub. No.: US 2021/0341642 A1
(43) Pub. Date: Nov. 4, 2021

(54) NESTED MODEL SIMULATIONS TO GENERATE SUBSURFACE REPRESENTATIONS

(71) Applicant: Chevron U.S.A. Inc., San Ramon, CA (US)

(72) Inventors: Ashley D. Harris, Houston, TX (US); Tao Sun, Missouri City, TX (US); Sarah E. Baumgardner, Houston, TX (US)

(21) Appl. No.: 15/929,390

(22) Filed: Apr. 30, 2020

(51) Int. Cl. G01V 99/00; G06F 30/20

(52) U.S. Cl. CPC G01V 99/005; G06F 30/20

(57) ABSTRACT

Process-based numerical forward stratigraphic models of different spatiotemporal scales may be nested to address subsurface characterization at different scales. Subsurface representations may be generated using an iterative loop in which subsurface representations are generated using different-scale subsurface models, compared to scale-appropriate data, and used to define boundary conditions/inputs for subsequently run subsurface models. Results from the subsurface models may be compared to one or more standards for quality control and/or for subsurface representation selection. A series of comprehensive subsurface representations may be generated, with the subsurface representations being constrained by different scales of information and physical plausible scenarios.

### FIELD

The present disclosure relates generally to the field of generating subsurface representations.

### BACKGROUND

Subsurface models are designed to generate representations of subsurface regions at different temporal and/or spatial scales. A single forward stratigraphic model designed for a certain stratigraphic or process scale may not be able to generate representations of subsurface regions with multiple scales. Mismatch between temporal and/or spatial scales of available data with the subsurface model may result in inefficient incorporation of the available data in generating subsurface representations.

### SUMMARY

This disclosure relates to generating subsurface representations. A first-scale subsurface model may be run for a first set of steps to generate a first-scale subsurface representation in a first-scale. A second-scale subsurface model may be run for a second set of steps to generate a second-scale subsurface representation in a second-scale different from the first-scale. A subsurface representation of a subsurface region may be generated based on the first-scale subsurface representation, the second-scale subsurface representation, and/or other information.

A system that generates subsurface representations may include one or more electronic storage, one or more processors and/or other components. The electronic storage may store information relating to different-scale subsurface models, information relating to sets of steps for different-scale subsurface models, information relating to different-scale subsurface representations, information relating to subsurface representation, and/or other information.

The processor(s) may be configured by machine-readable instructions. Executing the machine-readable instructions may cause the processor(s) to facilitate generating subsurface representations. The machine-readable instructions may include one or more computer program components. The computer program components may include one or more of a subsurface model component, a subsurface representation component, and/or other computer program components.

The subsurface model component may be configured to run different-scale subsurface models to generate different-scale subsurface representations in different scales. For example, the subsurface model component may be configured to run a first-scale subsurface model for a set of steps to generate a first-scale subsurface representation in a first-scale. The subsurface model component may be configured to run a second-scale subsurface model for a set of steps to generate a second-scale subsurface representation in a second-scale different from the first-scale.

In some implementations, a single step within the set of steps for the first-scale subsurface model may correspond to a first time duration. A single step within the set of steps for the second-scale subsurface model may correspond to a second time duration different from the first time duration. In some implementations, the different-scale subsurface models (e.g., the first-scale subsurface model, the second-scale subsurface model) may be process-based models and/or other models.

In some implementations, the first-scale may be larger than the second-scale. The second-scale subsurface representation may provide a finer-scale representation of a region of interest within the subsurface representation. The second-scale subsurface model may be run to generate the second-scale subsurface representation based on the region of interest within first-scale-subsurface representation and/or other information.

In some implementations, the first-scale may be smaller than the second-scale. The first-scale subsurface representation may provide a finer-scale representation of an initial condition region for generating the subsurface representation. The second-scale subsurface representation may provide a coarser-scale representation of the subsurface region.

In some implementations, the first-scale may be larger than the second-scale. The set of steps to run the first-scale subsurface model may include a number of steps to generate the first-scale subsurface representation as an initial portion of the subsurface representation. The initial portion may not include a region of interest. The sets of steps to run the second-scale subsurface model may include a number of steps to generate the second-scale subsurface representation as a subsequent region of the subsurface representation. The subsequent region of the subsurface representation may include a region of interest. In some implementations, interleaved running of the first-scale subsurface model and the second-scale subsurface model may be repeated until the subsurface representation of the subsurface region is generated.

In some implementations, quality of the second-scale subsurface representation may be analyzed to determine acceptability of the second-scale subsurface representation. The quality of the second-scale subsurface representation may be determined based on comparisons to field measurement data. Responsive to the second-scale subsurface representation being of unacceptable quality, input and/or constraint of the second-scale subsurface model may be modified to regenerate the second-scale subsurface representation. Responsive to the second-scale subsurface representation being of acceptable quality, input and/or constraint of the first-scale subsurface model may be determined based on the second-scale subsurface representation. In some implementations, quality of one of the first-scale subsurface representation and the second-scale subsurface representation may be determined based on other of the first-scale subsurface representation and the second-scale subsurface representation.

In some implementations, one or more additional subsurface models may be run to generate one or more scale subsurface representations in one or more scales different from the first-scale and different from the second-scale.

The subsurface representation component may be configured to generate a subsurface representation of a subsurface region based on different-scale subsurface representations and/or other information. For example, the subsurface representation component may be configured to generate a subsurface representation of a subsurface region based on the first-scale subsurface representation, the second-scale subsurface representation, and/or other information.

In some implementations, the first-scale may be larger than the second-scale. The first-scale subsurface representation may provide a coarser-scale representation of an initial condition region for generating the subsurface representation. The second-scale subsurface representation may provide a finer-scale representation of a region of interest within the subsurface representation. The subsurface representation may be generated based on replacement of the region of interest within the first-scale subsurface representation with the second-scale subsurface representation, and/or other information.

In some implementations, the first-scale may be smaller than the second-scale. The second-scale subsurface representation may provide a coarser-scale representation of the subsurface region. The second-scale subsurface model may be run to generate the subsurface representation based on the finer-scale representation of the initial condition region provided by the first-scale representation and/or other information.

In some implementations, the first-scale may be larger than the second-scale. The subsurface representation may be generated based on combination of the first-scale subsurface representation and the second-scale subsurface representation, and/or other information.

These and other objects, features, and characteristics of the system and/or method disclosed herein, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of “a,” “an,” and “the” include plural referents unless the context clearly dictates otherwise.

### BRIEF DESCRIPTION OF THE DRAWINGS

FIG. 1 illustrates an example system that generates subsurface representations.

FIG. 2 illustrates an example method for generating subsurface representations.

FIG. 3 illustrates an example process for generating subsurface representation by starting from a large-scale subsurface model.

FIG. 4 illustrates an example process for generating subsurface representation by starting from a small-scale subsurface model.

FIG. 5 illustrates an example process for generating subsurface representation by iteratively switching between a large-scale subsurface model and a small-scale subsurface model.

FIG. 6 illustrates an example subsurface representation.

FIG. 7 illustrates example scales of subsurface models.

### DETAILED DESCRIPTION

The present disclosure relates to generating subsurface representations. Process-based numerical forward stratigraphic models of different spatiotemporal scales may be nested to address subsurface characterization at different scales. Subsurface representations may be generated using an iterative loop in which subsurface representations are generated using different-scale subsurface models, compared to scale-appropriate data, and used to define boundary conditions/inputs for subsequently run subsurface models. Results from the subsurface models may be compared to one or more standards for quality control and/or for subsurface representation selection. A series of comprehensive subsurface representations may be generated, with the subsurface representations being constrained by different scales of information and physical plausible scenarios.

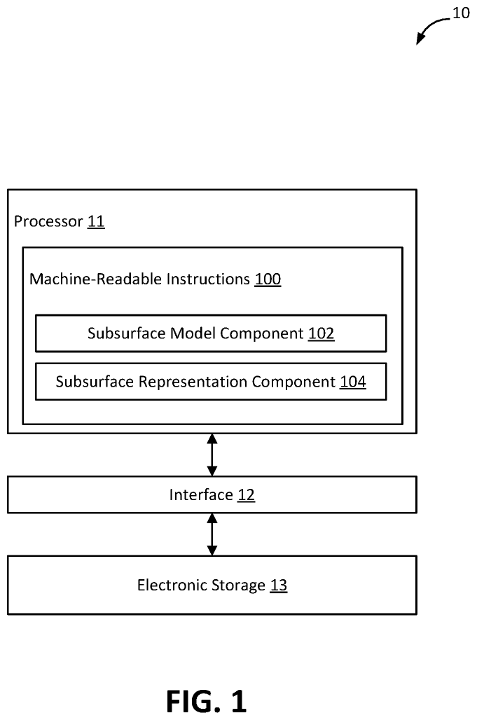

The methods and systems of the present disclosure may be implemented by and/or in a computing system, such as a system 10 shown in FIG. 1. The system 10 may include one or more of a processor 11, an interface 12 (e.g., bus, wireless interface), an electronic storage 13, and/or other components. A first-scale subsurface model may be run by the processor 11 for a first set of steps to generate a first-scale subsurface representation in a first-scale. A second-scale subsurface model may be run by the processor 11 for a second set of steps to generate a second-scale subsurface representation in a second-scale different from the first-scale. A subsurface representation of a subsurface region may be generated by the processor 11 based on the first-scale subsurface representation, the second-scale subsurface representation, and/or other information.

The electronic storage 13 may be configured to include electronic storage medium that electronically stores information. The electronic storage 13 may store software algorithms, information determined by the processor 11, information received remotely, and/or other information that enables the system 10 to function properly. For example, the electronic storage 13 may store information relating to different-scale subsurface models, information relating to sets of steps for different-scale subsurface models, information relating to different-scale subsurface representations, information relating to subsurface representation, and/or other information.

Numerical forward stratigraphic modeling (FSM) may simulate depositional processes, such as sediment erosion, transport, and deposition due to the interaction of intrinsic (e.g., auto retreat, channel avulsion, and migration) and extrinsic processes (e.g., climate, sea level, tectonism). FSMs may be able to integrate complex nonlinear interaction of intrinsic and extrinsic processes to provide physically and geologically plausible scenarios for subsurface regions/characteristics, such as reservoir, source rock, and seal distribution. FSMs may provide rigorous, repeatable, and transparent results by ensuring that the outputs are consistent with the basic laws of mass conservation, and sediment transport and dispersion behaviors. FSMs may effectively quantify risk and uncertainty in subsurface characterization with respect to reservoir presence, distribution, and connectivity.

A challenge in fully describing the subsurface characterization of a subsurface region, such as sedimentary basin, is that the assumptions of a given forward stratigraphic model are often designed for a certain stratigraphic and/or process scale. For example, large-scale models (e.g., basin-scale model) may be able to capture deposition over large spatial and/or temporal scales (e.g., kilometers—horizontal; thousands of years—vertical), thus making comparisons to seismic data a relatively straightforward process. However, large-scale models may not be able to capture the details necessary to investigate the fine scale (e.g., centimeters to meters—horizontal; and days to years—vertical) lithologic distributions and/or stratal architecture observed in core and well data. Such details may be more accurately simulated by small-scale models (e.g., reservoir-scale model) and may be paramount to understanding intra-reservoir connectivity. Thus, there is a mismatch between the spatial and temporal scales of available data and that of the models, which may complicate direct comparison and model conditioning efforts. For example, not all the available subsurface information may be incorporated by models of either scale to fully constrain the range of possible scenarios.

To overcome the above limitation, process-based models (e.g., process-based FSMs) may be nested to address subsurface characterization at different scales. Models of different scale may be nested within an iterative loop in which subsurface representations and/or portions of subsurface representations are (1) generated, (2) compared to scale appropriate data, and (3) used to define boundary conditions which are imposed on the subsequent model. Quality of the results from the models may be analyzed (e.g., compared to well logs and other field data sets) for quality control and/or model/subsurface representation selection. For example, the quality of the subsurface representations generated by the models of different scales may be determined based on comparisons to data from field measurement (field measurement data), such as seismic data sets, well logs, cores and other geology and geophysical data that may be available from the field of interest.

In some implementations, the quality of a subsurface representation generated by a model of one scale may be determined based on a subsurface representation generated by a model of a different scale. In a nesting of models of different scales, one scale may be used to validate and/or invalidate another scale model. For example, a finer-scale subsurface representation generated by a small-scale subsurface model may be used to validate and/or invalidate a coarser-scale subsurface representation generated by a large-scale subsurface model. A coarser-scale subsurface representation generated by a large-scale subsurface model may be used to validate and/or invalidate a finer-scale subsurface representation generated by a small-scale subsurface model. Such validation of different scales may be used when data to validate/invalidate a model/subsurface representation is not available in one scale but is available in another scale. For instance, field measurement data may not be available in one scale but available in another, or resolution may not be compatible in one scale but compatible in another scale. In such instances, validation of a model/surface representation in one scale may be delayed until a model in another scale is run/subsurface representation in another scale is generated.

The result of the iterative loop may include a series of comprehensive subsurface representations that are constrained by all scales of information and physically plausible scenarios, thereby appropriately characterizing risk and uncertainty in subsurface properties. Rather than simply decreasing the grid size of models, nesting geostatistical models within process-based models, or nesting multiple geostatistical models, the present disclosure utilize different process-based models (e.g., numerical stratigraphic models) in the nesting process to generate subsurface representations. Such utilization of different scale models enable more comprehensive generation of subsurface representations. For example, large-scale (e.g., basin-scale) model may benefit from more explicit comparison to fine-scale stratigraphy that constitutes the building blocks of basin fill, and small (e.g., reservoir-scale) model may benefit from the large-scale (e.g., basin-scale) context which influences the environment of deposition and availability, caliber, and/or mineralogy of sediment. Such utilization of different scale models enable the subsurface representation of a subsurface region to capture some level of physical processes at appropriate scales.

The processor 11 may be configured to provide information processing capabilities in the system 10. As such, the processor 11 may comprise one or more of a digital processor, an analog processor, a digital circuit designed to process information, a central processing unit, a graphics processing unit, a microcontroller, an analog circuit designed to process information, a state machine, and/or other mechanisms for electronically processing information. The processor 11 may be configured to execute one or more machine-readable instructions 100 to facilitate generating subsurface representations. The machine-readable instructions 100 may include one or more computer program components. The machine-readable instructions 100 may include one or more of a subsurface model component 102, a subsurface representation component 104, and/or other computer program components.

The subsurface model component 102 may be configured to run different-scale subsurface models to generate different-scale subsurface representations in different scales. In some implementations, the different-scale subsurface models may be process-based models and/or other models. A subsurface model may refer to a computer model (e.g., program, tool, script, function, process, algorithm) that simulates subsurface properties. A subsurface property may refer to attribute, quality, and/or characteristics of a region underneath the surface (subsurface region). Examples of subsurface properties simulated by a subsurface model may include types of subsurface materials, characteristics of subsurface materials, compositions of subsurface materials, arrangements/configurations of subsurface materials, physics of subsurface materials, and/or other subsurface properties. A subsurface model may simulate subsurface properties by generating one or more subsurface representations. A subsurface representation may refer to a computer-generated representation of a subsurface region, such as a one-dimensional, two-dimensional and/or three-dimensional model of the subsurface region. A subsurface representation may be defined by and/or include the subsurface properties simulated by the subsurface model.

An example of a subsurface model is a computational stratigraphy model. A computational stratigraphy model may refer to a computer model that simulates depositional and/or stratigraphic processes on a grain size scale while honoring physics-based flow dynamics. A computational stratigraphy model may simulate rock properties, such as velocity and density, based on rock-physics equations and assumptions. Input to a computational stratigraphy model may include information relating to a subsurface region to be simulated. For example, input to a computational stratigraphy model may include paleo basin floor topography, paleo flow and sediment inputs to the basin, and/or other information relating to the basin. In some implementations, input to a computational stratigraphy model may include one or more paleo geologic controls, such as climate changes, sea level changes, tectonics and other allocyclic controls. Output of a computational stratigraphy model may include one or more subsurface properties and/or one or more subsurface representations.

A computational stratigraphy model may include a forward stratigraphic model. A forward stratigraphic model may be fully based on physics of flow and sediment transport. A forward stratigraphic model may simulate one or more sedimentary processes that recreate the way stratigraphic successions develop and/or are preserved. The forward stratigraphic model may be used to numerically reproduce the physical processes that eroded, transported, deposited and/or modified the sediments over variable time periods. In a forward modelling approach, data may not be used as the anchor points for facies interpolation or extrapolation. Rather, data may be used to test and validate the results of the simulation. Stratigraphic forward modelling may be an iterative approach, where input parameters have to be modified until the results are validated by actual data. Usage of other subsurface models are contemplated.

[A subsurface model (e.g., computational stratigraphy model, forward stratigraphic model) may be run (e.g., executed) to generate one or more subsurface representations. A subsurface model may be run for a number of steps. A subsurface model may simulate building of a subsurface representation and/or changes in a subsurface representation by successively building and/or changing the subsurface representation over the steps by which the subsurface model is run. The steps for which a subsurface model is run may include time-steps. A time-step of a subsurface model may refer to an incremental change in time of the simulation run by the subsurface model. Individual steps of a subsurface model may correspond to a duration of time within the simulation. Running a subsurface model for a time-step may result in the time within the simulation changing (e.g., moving forward) by the corresponding duration of time.

For example, the subsurface model component 102 may be configured to run a first-scale subsurface model for a set of steps to generate a first-scale subsurface representation in a first-scale. The subsurface model component 102 may be configured to run a second-scale subsurface model for a set of steps to generate a second-scale subsurface representation in a second-scale different from the first-scale. A single step for different scale subsurface model may correspond to different time durations. A single step within the set of steps for the first-scale subsurface model may correspond to a first time duration. A single step within the set of step for the second-scale subsurface model may correspond to a second time duration different from the first time duration. Thus, the temporal resolution of different scale subsurface model may be different.

The size of step for a subsurface model may define the temporal resolution of the subsurface model. The size of step for a larger-scale subsurface model may define a larger temporal resolution (e.g., larger changes with individual time steps) than the size of step for a smaller-scale subsurface model. Similarly, the spatial resolution of different scale subsurface model may be different. A larger-scale subsurface model may generate portions of subsurface representation at larger extents at a time/per step than a smaller-scale subsurface model. Subsurface representation generated by different-scale subsurface models may provide different-scale representation of a subsurface region/a portion of a subsurface region. A subsurface representation generated by a smaller-scale subsurface model may provide a finer-scale representation of a subsurface region/a portion of a subsurface region. A subsurface representation generated by a larger-scale subsurface model may provide a coarser-scale representation of a subsurface region/a portion of a subsurface region. A finer-scale representation may include more granular simulation of the subsurface region/the portion of the subsurface region.

The subsurface model component 102 may be configured to run other-scale subsurface model(s) to generate other-scale subsurface representation(s) in other scale(s). In some implementations, a common dataset may be used to run subsurface models of different scales and/or to compare subsurface representation in different scales. The common dataset may be scaled based on the corresponding scale of the subsurface model/representation.

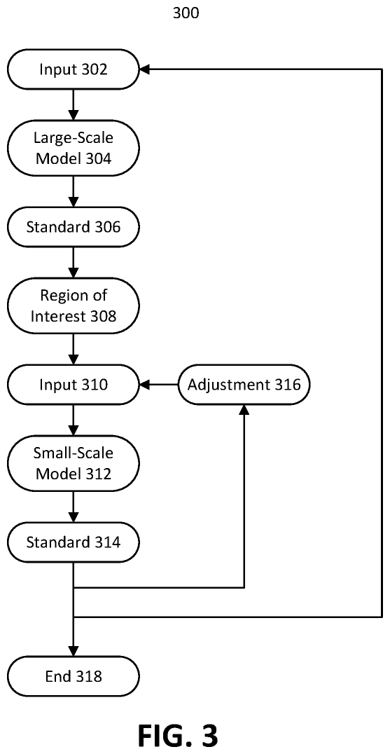

The subsurface model component 102 may be configured to run different-scale subsurface models in different sequences to generate different types of subsurface representations. FIGS. 3, 4, and 5 illustrate processes for generating subsurface representation using different sequences of different-scale subsurface models.

FIG. 3 illustrates an example process 300 for generating subsurface representation by starting from a large-scale subsurface model. The process 300 may include running of two different-scale subsurface model, with a larger-scale subsurface model being run before the smaller-scale subsurface model. That is, the scale of the subsurface model that is run first may be larger than the scale of the subsequently run subsurface model.

The process 300 may begin with an input step 302, in which input parameters to the large-scale (e.g., basin scale) subsurface model are identified. Input parameters may include values that define boundary/initial conditions and/or constraints for the subsurface model. Input parameters may include values that define initial/starting subsurface properties for the subsurface model. Examples of input parameters may include layer thickness, sediment discharge, water discharge, sediment accumulation rates, subsidence rates, sediment and water point source locations, water routing locations, sea level change, tectonic subsidence, compaction curve, and/or other input parameters. In some implementations, one or more of the input parameters may be determined from field and/or theoretical studies, inversion of field data using one or more optimization techniques, and/or other information. Input parameters to the large-scale subsurface model may be defined at larger scale (e.g., larger spatial lengths, longer time durations) than input parameters to the small-scale subsurface model.

A large-scale model step 304 may include running of the large-scale subsurface model for a number of steps based on the input parameters (identified in the input step 302) and/or other information. The large-scale subsurface model may be run to generate one or more coarser-scale subsurface representations in the coarser-scale. The coarser-scale subsurface representation(s) may include representation(s) of the entire subsurface region for which subsurface representation is to be generated.

A standard step 306 may include selection of subsurface representation(s) (generated in the large-scale model step 304) that satisfy one or more standards. For example, the standard step 306 may include selection of subsurface representation(s) that qualitatively and/or quantitatively meet a standard. In the standard step 306, the subsurface representation(s) may be compared to information that define desired subsurface properties of the subsurface region. For example, the subsurface representation(s) may be compared to large-scale stratal geometries, hypsometric and bathymetric data, sediment distribution, discretized well logs (and associated information derived from well log), sediment package thickness, grain size distribution to available field datasets, and/or other information to determine which of the subsurface representation(s) provide acceptable representation of the subsurface region. The selected subsurface representation(s) may be used for subsequent steps in the process 300. Use of other dataset to select acceptable subsurface representations are contemplated.

A region of interest step 308 may include identification of one or more regions of interest within the selected subsurface representation(s). A region of interest within a subsurface representation may refer to a portion of the subsurface representation for which finer-scale subsurface representation is desired. A region of interest may include one or more intervals of interest. A region of interest may be defined spatially (defined in spatial dimensions) and/or temporally (e.g., defined using deposition times). For example, a region of interest may be expressed as stratigraphic/lithologic boundaries and/or as timelines. A region of interest may be identified manually (e.g., user identification of depths of interest) and/or based on analysis (e.g., analysis of trends in a basin, analysis of subsurface properties simulated within the subsurface representation). A region of interest may be identified for finer-scale subsurface representation generation.

For example, it may be desirable to generate subsurface representation of a large subsurface region, such as a basin. Use of small-scale subsurface model to generate the entire subsurface representation of the large subsurface region may require consumption of large amount of resource (e.g., time, power, processing capability, memory) and/or may be impractical. Large-scale subsurface model may be used to generate coarse-scale subsurface representation of the large subsurface region, and regions of interest (e.g., reservoir interval, source rock, seal interval) within the coarse-scale subsurface representation may be identified so that the small-scale subsurface model may be used to generate representations of those regions of interest.

An input step 310 may include identification of input parameters to the small-scale (e.g., reservoir scale) subsurface model. The types of input parameters to the small-scale subsurface model may be the same as the types of input parameters to the large-scale subsurface model. The types of input parameters to the small-scale subsurface model may be different from the types of input parameters to the large-scale subsurface model. There may be overlap between the types of input parameters between the large-scale subsurface model and the small-scale subsurface model. The input parameters to the small-scale subsurface model may be identified based on the region of interest within the coarser-scale subsurface representation generated by the large-scale subsurface model. For example, data (e.g., layer thickness, sediment discharge, water discharge, sediment accumulation rates, subsidence rates, sediment and water point source locations, water routing locations, sea level change, tectonic subsidence, compaction curve) from the region of interest may be extracted for use as input parameters to the small-scale subsurface model. The data extracted from the region of interest may be scaled for use by the small-scale subsurface model. The small-scale subsurface model may be run to generate one or more finer-scale subsurface representations of one or more regions of interest based on the region(s) of interest within coarser-scale-subsurface representation and/or other information.

A small-scale model step 312 may include running of the small-scale subsurface model for a number of steps based on the input parameters (identified in the input step 310) and/or other information. The small-scale subsurface model may be run to generate one or more finer-scale subsurface representations of one or more regions of interest in the finer-scale. The finer-scale subsurface representation(s) may include representation(s) of the region(s) of interest within the coarser-scale subsurface representation generated by the large-scale subsurface model.

A standard step 314 may include determination of whether the quality of the finer-scale subsurface representation(s) generated by the small-scale subsurface model is acceptable or not. For example, the standard step 314 may include determination of whether the finer-scale subsurface representation(s) qualitatively and/or quantitatively meet one or more standards. For example, quality of the finer-scale subsurface representation(s) may be analyzed to determine acceptability of the finer-scale subsurface representation(s). For example, the finer-scale subsurface representation(s) may be compared to fine-scale stratal geometries, sediment distribution, well logs, core, sediment package thickness, grain size distribution, and/or other information to determine whether the finer-scale subsurface representation(s) provide acceptable representation(s) of the region(s) of interest. Responsive to the finer-scale subsurface representation(s) being of unacceptable quality (not providing acceptable representation(s) of the region(s) of interest), input parameters (e.g., input and/or constraint) of the small-scale subsurface model may be modified in an adjustment step 316 to regenerate the finer-scale subsurface representation(s).

Responsive to the finer-scale subsurface representation being of acceptable quality, the process 300 may end (step 318). In some implementations, responsive to the finer-scale subsurface representation being of acceptable quality, input parameters (e.g., input and/or constraint) of the large-scale subsurface model may be determined (e.g., set, adjusted) based on the finer-scale subsurface representation. For example, the input parameters of the small-scale subsurface model and/or results of the small-scale subsurface model may be returned to the large-scale subsurface model as inputs. In some implementations, the loop may continue until all scale of subsurface data are sufficiently matched. Such looping of data may enable coupling between the different-scale subsurface models. The coupling between the different-scale subsurface model may include tight coupling or loose coupling. For tight coupling, the data/result from the small-scale subsurface model may be fed back into the large-scale subsurface model to loop. For loosely coupling, the data/result from the small-scale subsurface model may not be fed back into the large-scale subsurface model based on the finer-scale subsurface representation(s) being of acceptable quality. As another example, coupling between the different-scale subsurface models may include a single-direction coupling or bi-direction coupling. In a single-direction coupling, data/result from the one-scale subsurface model may be fed into the other-scale subsurface mode, but not the other way around. In a bi-direction decoupling, data/result from the one-scale subsurface model may be fed into the other-scale subsurface mode in both ways. Other coupling between the different-scale subsurface models are contemplated.

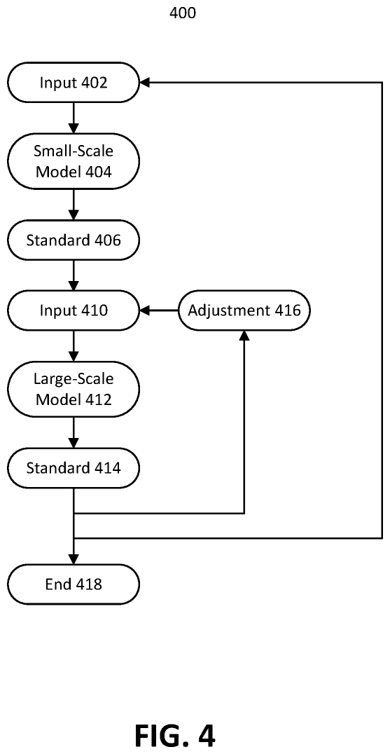

FIG. 4 illustrates an example process 400 for generating subsurface representation by starting from a small-scale subsurface model. The process 400 may include running of two different-scale subsurface model, with a smaller-scale subsurface model being run before the larger-scale subsurface model. That is, the scale of the subsurface model that is run first may be smaller than the scale of the subsequently run subsurface model.

The process 400 may begin with an input step 402, in which input parameters to the small-scale (e.g., reservoir scale) subsurface model are identified. Input parameters may include values that define initial/starting subsurface properties for the subsurface model. Examples of input parameters may include layer thickness, sediment discharge, water discharge, sediment accumulation rates, subsidence rates, sediment and water point source locations, water routing locations, sea level change, tectonic subsidence, compaction curve, and/or other input parameters. In some implementations, one or more of the input parameters may be determined from field and/or theoretical studies, inversion of field data using one or more optimization techniques, and/or other information. Input parameters to the small-scale subsurface model may be defined at smaller scale (e.g., smaller spatial lengths, shorter time durations) than input parameters to the large-scale subsurface model.

A small-scale model step 404 may include running of the small-scale subsurface model for a number of steps based on the input parameters (identified in the input step 402) and/or other information. The small-scale subsurface model may be run to generate one or more finer-scale subsurface representations in the finer-scale. The finer-scale subsurface representation(s) may include representation(s) of an initial condition region. The representation(s) of the initial condition region may be used to generate the subsurface representation of the subsurface region. The initial condition region may be part of the subsurface region (e.g., one or more initial/beginning layers of the subsurface region). The initial condition region may not be part of the subsurface region (e.g., one or more layers adjacent to/below/preceding the subsurface region).

A standard step 406 may include selection of subsurface representation(s) (generated in the small-scale model step 404) that satisfy one or more standards. For example, the standard step 406 may include selection of subsurface representation(s) that qualitatively and/or quantitatively meet a standard. In the standard step 406, the subsurface representation(s) may be compared to information that define desired subsurface properties of the initial condition region. For example, the subsurface representation(s) may be compared to reservoir-scale stratal geometries, sediment distribution, well logs, core, sediment package thickness, grain size distribution, and/or other information to determine which of the subsurface representation(s) provide acceptable representation of the initial condition region. The selected subsurface representation(s) may be used for subsequent steps in the process 400. Use of other dataset to select acceptable subsurface representations are contemplated.

An input step 410 may include identification of input parameters to the large-scale (e.g., basin scale) subsurface model. The types of input parameters to the large-scale subsurface model may be the same as the types of input parameters to the small-scale subsurface model. The types of input parameters to the large-scale subsurface model may be different from the types of input parameters to the small-scale subsurface model. There may be overlap between the types of input parameters between the small-scale subsurface model and the large-scale subsurface model.

The input parameters to the large-scale subsurface model may be identified based on the finer-scale subsurface representation selected at the standard step 406. For example, data (e.g., layer thickness, sediment discharge, water discharge, sediment accumulation rates, subsidence rates, sediment and water point source locations, water routing locations, sea level change, tectonic subsidence, compaction curve) from the finer-scale subsurface representation may be extracted for use as input parameters to the large-scale subsurface model. The data extracted from the finer-scale subsurface representation may be scaled for use by the large-scale subsurface model. Such determination of the input parameters may enable the large-scale subsurface model to run more accurately. The large-scale subsurface model may be run to generate one or more coarser-scale subsurface representations of the subsurface region based on the finer-scale-subsurface representation and/or other information.

A large-scale model step 412 may include running of the large-scale subsurface model for a number of steps based on the input parameters (identified in the input step 410) and/or other information. The large-scale subsurface model may be run to generate one or more coarser-scale subsurface representations of the subsurface region in the coarser-scale. The coarser-scale subsurface representation(s) may provide coarser-scale representation(s) of the subsurface region.

A standard step 414 may include determination of whether the quality of the coarser-scale subsurface representation(s) generated by the large-scale subsurface model is acceptable or not. For example, the standard step 414 may include determination of whether the coarser-scale subsurface representation(s) qualitatively and/or quantitatively meet one or more standards. For example, quality of the coarser-scale subsurface representation(s) may be analyzed to determine acceptability of the coarser-scale subsurface representation(s). For example, the coarser-scale subsurface representation(s) may be compared to large-scale stratal geometries, hypsometric and bathymetric data, sediment distribution, discretized well logs, sediment package thickness, grain size distribution, and/or other information to determine whether the coarser-scale subsurface representation(s) provide acceptable representation(s) of the subsurface region. Responsive to the coarser-scale subsurface representation(s) being of unacceptable quality (not providing acceptable representation(s) of the subsurface region), input parameters (e.g., input and/or constraint) of the large-scale subsurface model may be modified in an adjustment step 416 to regenerate the coarser-scale subsurface representation(s).

Responsive to the coarser-scale subsurface representation being of acceptable quality, the process 400 may end (step 418). In some implementations, responsive to the coarser-scale subsurface representation being of acceptable quality, input parameters (e.g., input and/or constraint) of the large-scale subsurface model may be determined (e.g., set, adjusted) based on the finer-scale subsurface representation. For example, the input parameters of the large-scale subsurface model and/or results of the large-scale subsurface model may be returned to the small-scale subsurface model as inputs. In some implementations, the loop may continue until all scale of subsurface data are sufficiently matched. Such looping of data may enable coupling between the different-scale subsurface models. The coupling between the different-scale subsurface model may include tight coupling or loose coupling. For tight coupling, the data/result from the large-scale subsurface model may be fed back into the small-scale subsurface model to loop. For loosely coupling, the data/result from the large-scale subsurface model may not be fed back into the small-scale subsurface model based on the coarser-scale subsurface representation(s) being of acceptable quality. As another example, coupling between the different-scale subsurface models may include a single-direction coupling or bi-direction coupling. Other coupling between the different-scale subsurface models are contemplated.

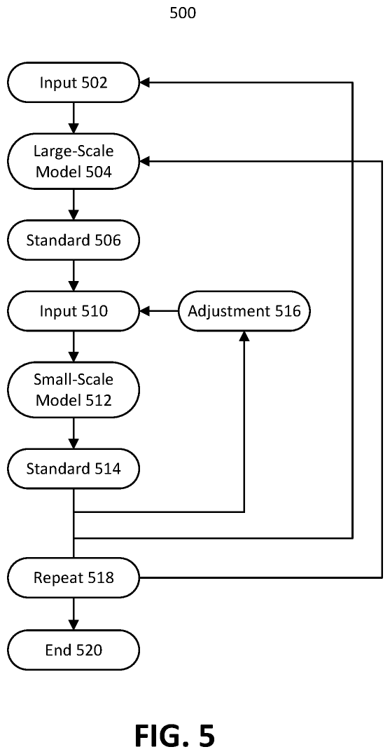

FIG. 5 illustrates an example process 500 for generating subsurface representation by iteratively switching between a large-scale subsurface model and a small-scale subsurface model. Iterative switching may continue until generation of the subsurface representation is completed. Coarser-scale subsurface representations and finer-scale subsurface representations may be generated in increments to be incorporated into the final subsurface representation.

While FIG. 5 shows the process 500 with the larger-scale subsurface model being run being the smaller-scale subsurface model, this is merely as an example and is not meant to be limiting. For example, the iteratively switching between two different-scale subsurface models may start with the smaller-scale subsurface model.

The process 500 may begin with an input step 502, in which input parameters to the large-scale (e.g., basin scale) subsurface model are identified. Input parameters may include values that define boundary/initial conditions and/or constraints for the subsurface model. Input parameters may include values that define initial/starting subsurface properties for the subsurface model. Examples of input parameters may include layer thickness, sediment discharge, water discharge, sediment accumulation rates, subsidence rates, sediment and water point source locations, water routing locations, sea level change, tectonic subsidence, compaction curve, and/or other input parameters. In some implementations, one or more of the input parameters may be determined from field and/or theoretical studies, inversion of field data using one or more optimization techniques, and/or other information. Input parameters to the large-scale subsurface model may be defined at larger scale (e.g., larger spatial lengths, longer time durations) than input parameters to the small-scale subsurface model.

A large-scale model step 504 may include running of the large-scale subsurface model for a number of steps based on the input parameters (identified in the input step 502) and/or other information. The large-scale subsurface model may be run to generate one or more coarser-scale subsurface representations in the coarser-scale. The coarser-scale subsurface representation(s) may include representation(s) of the one or more portions of the subsurface region for which subsurface representation is to be generated. The coarser-scale subsurface representation(s) may provide initial condition region(s) for generating the subsurface representation. The coarser-scale subsurface representation(s) may be generated as one or more initial portions of the final subsurface representation to be generated. The initial portion(s) may not include a region of interest within the subsurface region. That is, the large-scale may be run for a number of steps to generate portion(s) of the subsurface representation until a portion of the subsurface representation corresponding to a region of interest is reached. Running of the large-scale subsurface model may be switched with running of the small-scale subsurface model to generate one or more finer-scale subsurface representation for the region of interest.

A standard step 506 may include selection of subsurface representation(s) (generated in the large-scale model step 504) that satisfy one or more standards. For example, the standard step 506 may include selection of subsurface representation(s) that qualitatively and/or quantitatively meet a standard. In the standard step 506, the subsurface representation(s) may be compared to information that define desired subsurface properties of the initial portion(s) of the subsurface region. For example, the subsurface representation(s) may be compared to large-scale stratal geometries, hypsometric and bathymetric data, sediment distribution, discretized well logs (and associated information derived from well log), sediment package thickness, grain size distribution to available field datasets, and/or other information to determine which of the subsurface representation(s) provide acceptable representation of the initial portion(s) of the subsurface region. The selected subsurface representation(s) may be used for subsequent steps in the process 500. Use of other dataset to select acceptable subsurface representations are contemplated.

An input step 510 may include identification of input parameters to the small-scale (e.g., reservoir scale) subsurface model. The types of input parameters to the small-scale subsurface model may be the same as the types of input parameters to the large-scale subsurface model. The types of input parameters to the small-scale subsurface model may be different from the types of input parameters to the large-scale subsurface model. There may be overlap between the types of input parameters between the large-scale subsurface model and the small-scale subsurface model. The input parameters to the small-scale subsurface model may be identified based on the generated subsurface representation (e.g., the coarser-scale subsurface representation(s) of the initial portion(s) of the subsurface generated by the large-scale subsurface model. For example, data (e.g., layer thickness, sediment discharge, water discharge, sediment accumulation rates, subsidence rates, sediment and water point source locations, water routing locations, sea level change, tectonic subsidence, compaction curve) from the generated subsurface representation may be extracted for use as input parameters to the small-scale subsurface model. The data extracted from the generated subsurface representation may be scaled for use by the small-scale subsurface model. The small-scale subsurface model may be run to generate one or more finer-scale subsurface representations of one or more regions of interest based on the coarser-scale-subsurface representation(s) of the initial portion(s) and/or other information. The finer-scale subsurface representation(s) may correspond to the adjacent region (e.g., next in space and/or time) of the subsurface region. The small-scale subsurface model may be run to generate one or more subsequent regions of the subsurface representation based on the coarser-scale representation of the initial condition region(s) provided by the coarser-scale subsurface representation. For example, the small-scale subsurface model may be run to generate a subsequent region of the subsurface representation based on the coarser-scale representation of flow and sedimentary condition in an initial condition region provided by the coarser-scale representation.

A small-scale model step 512 may include running of the small-scale subsurface model for a number of steps based on the input parameters (identified in the input step 510) and/or other information. The small-scale subsurface model may be run to generate one or more finer-scale subsurface representations of one or more regions of interest in the finer-scale. The finer-scale subsurface representation(s) may include representation(s) of the region(s) of interest within the final subsurface representation to be generated. The finer-scale subsurface representation(s) may be generated as the subsequent (e.g., in space and/or time) region of the final subsurface representation to be generated. Thus, the large-scale subsurface model may be used to generate the portion(s) of the final subsurface representation not including region(s) of interest in coarse-scale and the small-scale subsurface model may be used to generate the portion(s) of the final subsurface representation including region(s) of interest in fine-scale.

A standard step 514 may include determination of whether the quality of the finer-scale subsurface representation(s) generated by the small-scale subsurface model is acceptable or not. For example, the standard step 514 may include determination of whether the finer-scale subsurface representation(s) qualitatively and/or quantitatively meet one or more standards. For example, quality of the finer-scale subsurface representation(s) may be analyzed to determine acceptability of the finer-scale subsurface representation(s). For example, the finer-scale subsurface representation(s) may be compared to fine-scale stratal geometries, sediment distribution, well logs, core, sediment package thickness, grain size distribution, and/or other information to determine whether the finer-scale subsurface representation(s) provide acceptable representation(s) of the region(s) of interest. Responsive to the finer-scale subsurface representation(s) being of unacceptable quality (not providing acceptable representation(s) of the region(s) of interest), input parameters (e.g., input and/or constraint) of the small-scale subsurface model may be modified in an adjustment step 516 to regenerate the finer-scale subsurface representation(s).

Responsive to the finer-scale subsurface representation being of acceptable quality, the steps 504, 506, 510, 512, 514, 516 may be repeated (step 518). Input parameters to the large-scale (e.g., basin scale) subsurface model may be identified from the finer-scale subsurface representation. The repeat step 518 may include repetition of the interleaved running of the large-scale subsurface model and the small-scale subsurface model. The interleaved running of the different-scale subsurface models may be repeated until the subsurface representation of the subsurface region is generated. For example, the interleaved running of the different-scale subsurface models may be repeated until the desired thickness and/or time of the subsurface representation is reached. The process 500 may end (step 520) when the subsurface representation of the subsurface region is generated.

In some implementations, responsive to the finer-scale subsurface representation being of acceptable quality, input parameters (e.g., input and/or constraint) of the large-scale subsurface model may be determined (e.g., set, adjusted) based on the finer-scale subsurface representation. For example, the input parameters of the small-scale subsurface model and/or results of the small-scale subsurface model may be returned to the large-scale subsurface model as inputs. In some implementations, the loop may continue until all scale of subsurface data are sufficiently matched. Such looping of data may enable coupling between the different-scale subsurface models. The coupling between the different-scale subsurface model may include tight coupling or loose coupling. For tight coupling, the data/result from the small-scale subsurface model may be fed back into the large-scale subsurface model to loop. For loosely coupling, the data/result from the small-scale subsurface model may not be fed back into the large-scale subsurface model based on the finer-scale subsurface representation(s) being of acceptable quality. As another example, coupling between the different-scale subsurface models may include a single-direction coupling or bi-direction coupling. In a single-direction coupling, data/result from the one-scale subsurface model may be fed into the other-scale subsurface mode, but not the other way around. In a bi-direction decoupling, data/result from the one-scale subsurface model may be fed into the other-scale subsurface mode in both ways. Other coupling between the different-scale subsurface models are contemplated.

The subsurface representation component 104 may be configured to generate a subsurface representation of a subsurface region based on different-scale subsurface representations and/or other information. For example, the subsurface representation component 104 may be configured to generate a subsurface representation of a subsurface region based on the first-scale subsurface representation (generated through the first-scale subsurface model), the second-scale subsurface representation (generated through the second-scale subsurface model), and/or other information. The use of the different-scale subsurface representations in generating the subsurface representation of the subsurface region may depend on how the different-scale subsurface models were nested to generate the different-scale subsurface representations.

For example, with respect to the process 300 shown in FIG. 3, the large-scale subsurface model may be used to generate a coarser-scale representation of the subsurface region. The small-scale subsurface model may be used to generate one or more finer-scale representations of the region(s) of interest within the subsurface region/the subsurface representation of the subsurface region. The subsurface region of the subsurface region may be generated based on replacement of the region(s) of interest within the coarser-scale subsurface representation with the finer-scale subsurface representation(s), and/or other information. The finer-scale subsurface representation(s) of the region(s) of interest may be inserted into the coarser-scale subsurface representation of the subsurface region. Thus, the subsurface representation of the subsurface region may include finer-scale portions for the region(s) of interest and coarser-scale portions for other regions.

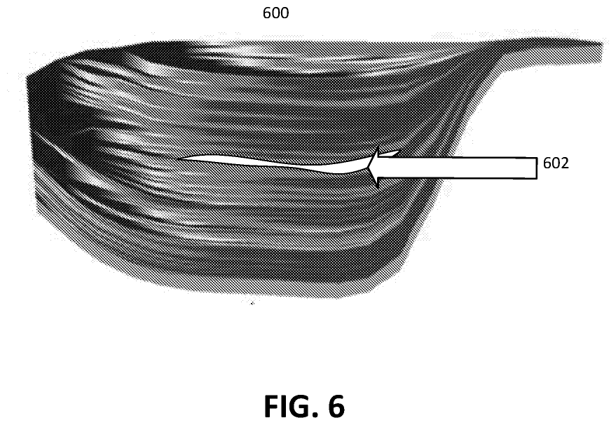

FIG. 6 illustrates an example subsurface representation 600 of a subsurface region. The subsurface representation 600 may include a portion 602. The portion 602 of the subsurface representation 600 may represent a region of interest within the subsurface region. To generate the subsurface representation 600, the large-scale subsurface model may be run to generate a coarser-scale subsurface representation of the subsurface region. The information from the coarser-scale representation of the subsurface region (e.g., information relating to the portion 602 from the coarser-scale representation) may be used to run a small-scale subsurface model and generate a finer-scale subsurface representation for the portion 602. The finer-scale subsurface representation may be inserted into the portion 602 of the coarser-scale subsurface representation of the subsurface region to generate the surface representation 600 of the subsurface region. Such generation of the subsurface representation may take advantage of both the faster/less-resource intensive generation of subsurface representation provided by the large-scale subsurface model and more detailed/granular subsurface representation provided by the small-scale subsurface model. In some implementations, the output of the detailed/granular subsurface representation may be compared to fine-scale information (e.g., fine-scale stratal geometries, sediment distribution, well logs, core, sediment package thickness, grain size distribution), and then compared back to the coarser-scale subsurface representation.

For example, with respect to the process 400 shown in FIG. 4, the small-scale subsurface model may be used to generate a finer-scale representation of initial condition region(s) for the subsurface region. The small-scale subsurface model may be used to generate one or more finer-scale representations of the initial condition region(s) within, at the boundary of, and/or outside the subsurface region/the subsurface representation of the subsurface region. The subsurface region of the subsurface region may be generated based on by running the large-scale subsurface model using information from the initial condition region(s). That is, a coarser-scale subsurface representation of the subsurface region may be generated by using the output of the finer-scale subsurface representation(s) of the initial condition region(s). The coarser-scale subsurface representation of the subsurface region may be generated as the subsurface representation of the subsurface region.

As another example, with respect to the process 500 shown in FIG. 5, the small-scale subsurface model may be used to generate finer-scale representation of region(s) of interest within the subsurface region, and the large-scale subsurface model may be used to generate coarser-scale representation of other regions within the subsurface region. The finer-scale representation of region(s) of interest and coarser-scale representation of other regions within the subsurface region may be combined to generate the subsurface representation of the subsurface region. For example, the finer-scale representation of region(s) of interest and coarser-scale representation of other regions within the subsurface region may be stacked based on spatial and/or temporal locations of the representations. The stacked subsurface representation may include detailed/granular portion(s) for the region(s) of interest and less detailed/granular portion(s) for other regions.

While nesting of different-scale subsurface models have been described with respect to a small-scale subsurface model and a large-scale subsurface model, this is merely as an example and is not meant to be limiting. In some implementations, more than two different-scale subsurface models may be run to generate additional subsurface representations in one or more other scales. For example, in addition to a reservoir-scale subsurface model and a basin-scale subsurface model, one or more additional subsurface models may be run to generate one or more scale subsurface representations in one or more scales different from the reservoir-scale and different from the basin-scale. The subsurface model may be run based on the granularity of details desired in the subsurface representation. That is, the subsurface model with scale that matches the desired spatial and/or temporal resolution of the subsurface representation simulation may be selected (e.g., used in nested loop) to generate different portions of the subsurface representation of the subsurface region.

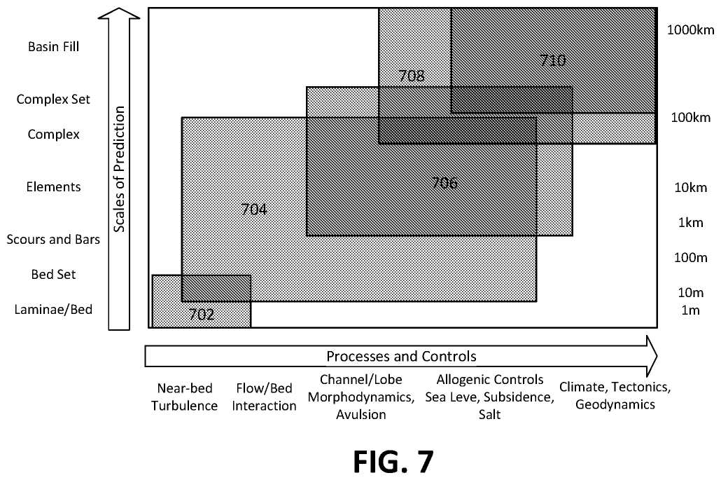

FIG. 7 illustrates example scales of subsurface models. For example, five different subsurface models may correspond to five different scales 702, 704, 706, 708, 710. Subsurface models of smaller scale may generate more detailed/granular subsurface representation at the cost of higher resource consumption (e.g., more computationally expensive/time-consuming). Depending on the desired spatial and/or temporal resolution of the subsurface representation simulation, one or more of the subsurface models may be run. For example, to simulate laminae/bed for near-bed turbulence, a subsurface model corresponding to the scale 702 may be run. To simulate elements for allogenic controls, a subsurface model corresponding to the scale 706 may be run. In some implementation, one or more intermediary subsurface models may be run to connect subsurface representations of non-adjacent/non-overlapping scales. For example, to connect a portion of the subsurface represented generated in the scale 702 with a portion of the subsurface represented generated in the scale 706, a subsurface model corresponding to the scale 704 may be run to generate an intermediary portion for the two portions. Subsurface models of different spatiotemporal scales may be nested to address subsurface characterization at different scales. Subsurface models of adjacent/overlapping scales may be used to link through different scales within the nested model process. Other scales of subsurface models are contemplated.

Implementations of the disclosure may be made in hardware, firmware, software, or any suitable combination thereof. Aspects of the disclosure may be implemented as instructions stored on a machine-readable medium, which may be read and executed by one or more processors. A machine-readable medium may include any mechanism for storing or transmitting information in a form readable by a machine (e.g., a computing device). For example, a tangible computer-readable storage medium may include read-only memory, random access memory, magnetic disk storage media, optical storage media, flash memory devices, and others, and a machine-readable transmission media may include forms of propagated signals, such as carrier waves, infrared signals, digital signals, and others. Firmware, software, routines, or instructions may be described herein in terms of specific exemplary aspects and implementations of the disclosure, and performing certain actions.

In some implementations, some or all of the functionalities attributed herein to the system 10 may be provided by external resources not included in the system 10. External resources may include hosts/sources of information, computing, and/or processing and/or other providers of information, computing, and/or processing outside of the system 10.

Although the processor 11 and the electronic storage 13 are shown to be connected to the interface 12 in FIG. 1, any communication medium may be used to facilitate interaction between any components of the system 10. One or more components of the system 10 may communicate with each other through hard-wired communication, wireless communication, or both. For example, one or more components of the system 10 may communicate with each other through a network. For example, the processor 11 may wirelessly communicate with the electronic storage 13. By way of non-limiting example, wireless communication may include one or more of radio communication, Bluetooth communication, Wi-Fi communication, cellular communication, infrared communication, or other wireless communication. Other types of communications are contemplated by the present disclosure.

Although the processor 11 is shown in FIG. 1 as a single entity, this is for illustrative purposes only. In some implementations, the processor 11 may comprise a plurality of processing units. These processing units may be physically located within the same device, or the processor 11 may represent processing functionality of a plurality of devices operating in coordination. The processor 11 may be separate from and/or be part of one or more components of the system 10. The processor 11 may be configured to execute one or more components by software; hardware; firmware; some combination of software, hardware, and/or firmware; and/or other mechanisms for configuring processing capabilities on the processor 11.

It should be appreciated that although computer program components are illustrated in FIG. 1 as being co-located within a single processing unit, one or more of computer program components may be located remotely from the other computer program components. While computer program components are described as performing or being configured to perform operations, computer program components may comprise instructions which may program processor 11 and/or system 10 to perform the operation.

While computer program components are described herein as being implemented via processor 11 through machine-readable instructions 100, this is merely for ease of reference and is not meant to be limiting. In some implementations, one or more functions of computer program components described herein may be implemented via hardware (e.g., dedicated chip, field-programmable gate array) rather than software. One or more functions of computer program components described herein may be software-implemented, hardware-implemented, or software and hardware-implemented

The description of the functionality provided by the different computer program components described herein is for illustrative purposes, and is not intended to be limiting, as any of computer program components may provide more or less functionality than is described. For example, one or more of computer program components may be eliminated, and some or all of its functionality may be provided by other computer program components. As another example, processor 11 may be configured to execute one or more additional computer program components that may perform some or all of the functionality attributed to one or more of computer program components described herein.

The electronic storage media of the electronic storage 13 may be provided integrally (i.e., substantially non-removable) with one or more components of the system 10 and/or as removable storage that is connectable to one or more components of the system 10 via, for example, a port (e.g., a USB port, a Firewire port, etc.) or a drive (e.g., a disk drive, etc.). The electronic storage 13 may include one or more of optically readable storage media (e.g., optical disks, etc.), magnetically readable storage media (e.g., magnetic tape, magnetic hard drive, floppy drive, etc.), electrical charge-based storage media (e.g., EPROM, EEPROM, RAM, etc.), solid-state storage media (e.g., flash drive, etc.), and/or other electronically readable storage media. The electronic storage 13 may be a separate component within the system 10, or the electronic storage 13 may be provided integrally with one or more other components of the system 10 (e.g., the processor 11). Although the electronic storage 13 is shown in FIG. 1 as a single entity, this is for illustrative purposes only. In some implementations, the electronic storage 13 may comprise a plurality of storage units. These storage units may be physically located within the same device, or the electronic storage 13 may represent storage functionality of a plurality of devices operating in coordination.

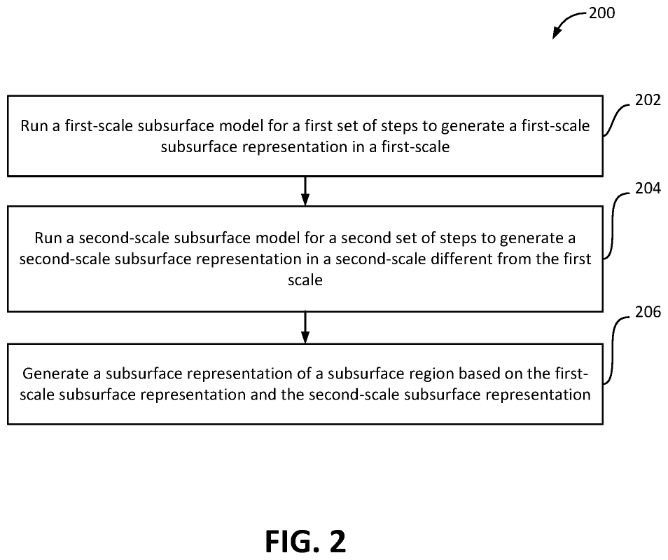

FIG. 2 illustrates method 200 for generating subsurface representations. The operations of method 200 presented below are intended to be illustrative. In some implementations, method 200 may be accomplished with one or more additional operations not described, and/or without one or more of the operations discussed. In some implementations, two or more of the operations may occur substantially simultaneously.

In some implementations, method 200 may be implemented in one or more processing devices (e.g., a digital processor, an analog processor, a digital circuit designed to process information, a central processing unit, a graphics processing unit, a microcontroller, an analog circuit designed to process information, a state machine, and/or other mechanisms for electronically processing information). The one or more processing devices may include one or more devices executing some or all of the operations of method 200 in response to instructions stored electronically on one or more electronic storage media. The one or more processing devices may include one or more devices configured through hardware, firmware, and/or software to be specifically designed for execution of one or more of the operations of method 200.

Referring to FIG. 2 and method 200, at operation 202, a first-scale subsurface model may be run for a first set of steps to generate a first-scale subsurface representation in a first-scale. In some implementation, operation 202 may be performed by a processor component the same as or similar to the subsurface model component 102 (Shown in FIG. 1 and described herein).

At operation 204, a second-scale subsurface model may be run for a second set of steps to generate a second-scale subsurface representation in a second-scale different from the first-scale. In some implementation, operation 204 may be performed by a processor component the same as or similar to the subsurface model component 102 (Shown in FIG. 1 and described herein).

At operation 206, a subsurface representation of a subsurface region may be generated based on the first-scale subsurface representation, the second-scale subsurface representation, and/or other information. In some implementation, operation 206 may be performed by a processor component the same as or similar to the subsurface representation component 104 (Shown in FIG. 1 and described herein).

Although the system(s) and/or method(s) of this disclosure have been described in detail for the purpose of illustration based on what is currently considered to be the most practical and preferred implementations, it is to be understood that such detail is solely for that purpose and that the disclosure is not limited to the disclosed implementations, but, on the contrary, is intended to cover modifications and equivalent arrangements that are within the spirit and scope of the appended claims. For example, it is to be understood that the present disclosure contemplates that, to the extent possible, one or more features of any implementation can be combined with one or more features of any other implementation.

What is claimed is:

1. A system for generating subsurface representations, the system comprising:
one or more physical processors configured by machine-readable instructions to:
run a first-scale subsurface model for a first set of steps to generate a first-scale subsurface representation in a first-scale;
run a second-scale subsurface model for a second set of steps to generate a second-scale subsurface representation in a second-scale different from the first-scale; and
generate a subsurface representation of a subsurface region based on the first-scale subsurface representation and the second-scale subsurface representation.

2. The system of claim 1, wherein the first-scale subsurface model and the second-scale subsurface model are process-based models.

3. The system of claim 1, wherein:
the first-scale is larger than the second-scale;
the second-scale subsurface representation provides a finer-scale representation of a region of interest within the subsurface representation;
the second-scale subsurface model is run to generate the second-scale subsurface representation based on the region of interest within first-scale-subsurface representation; and
the subsurface representation is generated based on replacement of the region of interest within the first-scale subsurface representation with the second-scale subsurface representation.

4. The system of claim 1, wherein:
the first-scale is smaller than the second-scale;
the first-scale subsurface representation provides a finer-scale representation of an initial condition region for generating the subsurface representation;
the second-scale subsurface representation provides a coarser-scale representation of the subsurface region; and
the second-scale subsurface model is run to generate the subsurface representation based on the finer-scale representation of the initial condition region provided by the first-scale representation.

5. The system of claim 1, wherein:
the first-scale is larger than the second-scale;
the first set of steps include a first number of steps to generate the first-scale subsurface representation as an initial portion of the subsurface representation, the initial portion not including a region of interest, wherein the first-scale subsurface representation provides a coarser-scale representation of an initial condition region for generating the subsurface representation; and
the second sets of steps include a second number of steps to generate the second-scale subsurface representation as a subsequent region of the subsurface representation, the subsequent region of the subsurface representation including a region of interest; and
the subsurface representation is generated based on combination of the first-scale subsurface representation and the second-scale subsurface representation.

6. The system of claim 5, wherein the second-scale subsurface model is run to generate the subsequent region of the subsurface representation based on the coarser-scale representation of the initial condition region provided by the first-scale subsurface representation.

7. The system of claim 6, wherein the second-scale subsurface model is run to generate the subsequent region of the subsurface representation based on the coarser-scale representation of flow and sedimentary condition in the initial condition region provided by the first-scale representation.

8. The system of claim 7, wherein interleaved running of the first-scale subsurface model and the second-scale subsurface model is repeated until the subsurface representation of the subsurface region is generated.

9. The system of claim 1, wherein:
quality of the second-scale subsurface representation is analyzed to determine acceptability of the second-scale subsurface representation;
responsive to the second-scale subsurface representation being of unacceptable quality, input and/or constraint of the second-scale subsurface model is modified to regenerate the second-scale subsurface representation.

10. The system of claim 9, wherein the quality of the second-scale subsurface representation is determined based on comparisons to field measurement data.

11. The system of claim 9, wherein:
responsive to the second-scale subsurface representation being of acceptable quality, input and/or constraint of the first-scale subsurface model is determined based on the second-scale subsurface representation.

12. The system of claim 1, wherein quality of one of the first-scale subsurface representation and the second-scale subsurface representation is determined based on other of the first-scale subsurface representation and the second-scale subsurface representation.

13. The system of claim 1, wherein one or more additional subsurface models are run to generate one or more scale subsurface representations in one or more scales different from the first-scale and different from the second-scale.

14. The system of claim 1, wherein a single step within the first set of steps corresponds to a first time duration and a single step within the second set of step corresponds to a second time duration different from the first time duration.

15. A method for generating subsurface representations, the method comprising:
running a first-scale subsurface model for a first set of steps to generate a first-scale subsurface representation in a first-scale;
running a second-scale subsurface model for a second set of steps to generate a second-scale subsurface representation in a second-scale different from the first-scale; and
generating a subsurface representation of a subsurface region based on the first-scale subsurface representation and the second-scale subsurface representation.

16. The method of claim 15, wherein:
the first-scale is larger than the second-scale;
the second-scale subsurface representation provides a finer-scale representation of a region of interest within the subsurface representation;
the second-scale subsurface model is run to generate the second-scale subsurface representation based on the region of interest within first-scale-subsurface representation; and
the subsurface representation is generated based on replacement of the region of interest within the first-scale subsurface representation with the second-scale subsurface representation.

17. The method of claim 15, wherein:
the first-scale is smaller than the second-scale;
the first-scale subsurface representation provides a finer-scale representation of an initial condition region for generating the subsurface representation;
the second-scale subsurface representation provides a coarser-scale representation of the subsurface region; and
the second-scale subsurface model is run to generate the subsurface representation based on the finer-scale representation of the initial condition region provided by the first-scale representation.

18. The method of claim 15, wherein:
the first-scale is larger than the second-scale;
the first set of steps include a first number of steps to generate the first-scale subsurface representation as an initial portion of the subsurface representation, the initial portion not including a region of interest, wherein the first-scale subsurface representation provides a coarser-scale representation of an initial condition region for generating the subsurface representation; and
the second sets of steps include a second number of steps to generate the second-scale subsurface representation as a subsequent region of the subsurface representation, the subsequent region of the subsurface representation including a region of interest; and
the subsurface representation is generated based on combination of the first-scale subsurface representation and the second-scale subsurface representation.

19. The method of claim 18, wherein the second-scale subsurface model is run to generate the subsequent region of the subsurface representation based on the coarser-scale representation of the initial condition region provided by the first-scale subsurface representation

20. The method of claim 19, wherein interleaved running of the first-scale subsurface model and the second-scale subsurface model is repeated until the subsurface representation of the subsurface region is generated.
